(19) United States
(12) Patent Application Publication
(10) Pub. No.: US 2022/0067031 A1
(43) Pub. Date: Mar. 3, 2022

(54) ULTRAVIOLET PROTECTION FACTOR CALCULATING APPARATUS AND ULTRAVIOLET PROTECTION FACTOR CALCULATING METHOD

(71) Applicant: LG HOUSEHOLD & HEALTH CARE LTD., Seoul (KR)

(72) Inventors: Ji Yong SHIM, Seoul (KR); Sun Gyoo PARK, Seoul (KR)

(73) Assignee: LG HOUSEHOLD & HEALTH CARE LTD., Seoul (KR)

(21) Appl. No.: 17/299,485

(22) PCT Filed: May 17, 2019
(86) PCT No.: PCT/KR2019/005894

§ 371 Date: Jun. 3, 2021

(30) Foreign Application Priority Data
Dec. 4, 2018 (KR) 10-2018-0154425

(51) Int. Cl. G06F 16/23; G06N 5/02; G01N 21/33

(52) U.S. Cl. CPC G06F 16/2379; G01N 21/33; G06N 5/02

(57) ABSTRACT

The present invention relates to an ultraviolet protection factor calculating apparatus and an ultraviolet protection factor calculating method for calculating an ultraviolet protection factor according to information of a cosmetic without a measurement experiment. The method may comprise the steps of: storing a database including a plurality of cosmetics and ultraviolet protection factors corresponding to the plurality of cosmetics, respectively; on the basis of the database, generating a decision tree in which the cosmetic ingredients included in the plurality of cosmetics are explanatory variables and an ultraviolet protection factor is a dependent variable; receiving an input of information of a cosmetic; and outputting the ultraviolet protection factor of the cosmetic, the information of which has been input, according to the decision tree.

### TECHNICAL FIELD

The present invention relates to an ultraviolet protection factor calculating apparatus and an ultraviolet protection factor calculating method, and more particularly, to an ultraviolet protection factor calculating apparatus and an ultraviolet protection factor calculating method for automatically calculating an ultraviolet protection factor of a cosmetic.

### BACKGROUND ART

Ultraviolet rays (UVR) refer to a ray having a wavelength of 200 to 400 nanometers (nm) among sunlight rays reaching the surface.

Ultraviolet rays are classified into ultraviolet ray A, ultraviolet ray B, and ultraviolet ray C according to a wavelength band, and the ultraviolet ray A is a ultraviolet ray having a wavelength of 320 to 400 nm, which is a main cause of skin aging and wrinkles, and the ultraviolet ray B is a ultraviolet ray having a wavelength of 290 to 320 nm, which is known to cause skin aging, skin cancer, cataracts, etc., and the ultraviolet ray C is a ultraviolet ray having a wavelength of 200 to 290 nm, which has a high probability of causing skin cancer, but is filtered by the atmospheric layer and rarely reaches the Earth.

An ultraviolet protection factor is an index for objectively indicating an ultraviolet protection effect, and includes SPF and PFA (PA).

SPF stands for sun protection factor (SPF), which refers to the protection effect of the ultraviolet ray B. SPF is a value obtained by dividing a minimum erythema dose obtained when applying an ultraviolet protection product by a minimum erythema dose obtained without applying the ultraviolet protection product, and is generally represented by a specific numerical value.

PFA (PA) stands for protection factor of UVA, which refers to the protection effect of the ultraviolet ray A. PFA is a value obtained by dividing a Minimal Persistent Pigment darkening Dose obtained when applying the ultraviolet protection product by a Minimal Persistent Pigment darkening Dose obtained without applying the ultraviolet protection product. PFA is generally represented by PA+, PA++, etc., which refers that the protection effect doubles every time the number of + symbols increase.

As described above, ultraviolet protection factors of conventional SPF, PFA, and the like are calculated through measurement experiments. In this case, since ultraviolet rays should be applied to a test subject for a certain period of time during the measurement experiment, there are problems such as a harmful effect on the test subject and taking a lot of time for the experiment.

### DISCLOSURE

### Technical Problem

An object of the present invention is directed to providing an ultraviolet protection factor calculating apparatus and an ultraviolet protection factor calculating method for calculating an ultraviolet protection factor according to cosmetic information without a measurement experiment.

Another object of the present invention is directed to providing an ultraviolet protection factor calculating apparatus and an ultraviolet protection factor calculating method for calculating an ultraviolet protection factor based on a database for an already produced cosmetic.

### Technical Solution

An ultraviolet protection factor calculating method of an ultraviolet protection factor calculating apparatus according to an embodiment of the present invention may include storing a database including data that maps cosmetic information and an ultraviolet protection factor for each of a plurality of cosmetics, generating a decision tree in which the cosmetic information included in the plurality of cosmetics is an explanatory variable and the ultraviolet protection factor is a dependent variable based on the database, receiving an input of cosmetic information, and outputting the ultraviolet protection factor of the cosmetic for which the information is input according to the decision tree.

The generating of the decision tree may include generating a decision tree when the explanatory variable further includes at least one piece of sub-information in addition to a cosmetic raw material.

The sub-information may include at least one of a skin type, minimum erythema dose, pigment presence, pigment grade TiO₂ concentration, product formulation, and product type.

The outputting of the ultraviolet protection factor may include outputting a sun protection factor (SPF) or a protection factor of UVA (PFA) calculated according to the decision tree.

The ultraviolet protection factor calculating method may further include receiving a decision tree update command, updating the database by storing cosmetic information and the ultraviolet protection factor determined according to the cosmetic information in the database when the decision tree update command is received; and regenerating the decision tree based on the updated database.

An ultraviolet protection factor calculating apparatus according to an embodiment of the present invention may include an input unit receiving an input of cosmetic information, a memory storing a database including data that maps cosmetic information and an ultraviolet protection factor for each of a plurality of cosmetics, a decision tree generation unit generating a decision tree in which the cosmetic information included in the plurality of cosmetics is an explanatory variable and the ultraviolet protection factor is a dependent variable based on the database, a control unit having an ultraviolet protection factor calculating unit that calculates the ultraviolet protection factor of the cosmetic for which the information is input through the input unit according to the decision tree, and an output unit outputting the ultraviolet protection factor calculated through the decision tree.

The control unit may generate the decision tree by further setting the cosmetic raw material and at least one piece of sub-information as the explanatory variable.

The sub-information may include at least one of a skin type, minimum erythema dose, pigment presence, pigment grade TiO₂ concentration, product formulation, and product type.

The output unit may output a sun protection factor (SPF) or a protection factor of UVA (PFA) calculated according to the decision tree.

The control unit may update the database by storing cosmetic information when a decision tree update command is received and the ultraviolet protection factor determined according to the received cosmetic information in the database, and may regenerate the decision tree based on the updated database.

### Advantageous Effects

According to an embodiment of the present invention, when cosmetic information is input, an ultraviolet protection factor is calculated according to a previously generated decision tree, and thus a separate experiment for measuring the ultraviolet protection factor is not required, and there is an advantage that a time required for measurement can be shortened and the measurement cost can be reduced.

In addition, since it is not necessary to apply ultraviolet rays to a test subject, there is an advantage that a harmful effect on the test subject when calculating the ultraviolet protection factor can be minimized.

In addition, since a decision tree is generated based on a database having a plurality of cosmetics and the ultraviolet protection factors corresponding thereto, and the ultraviolet protection factor is calculated according to the generated decision tree, there is an advantage that a prediction accuracy of the ultraviolet protection factor is improved.

In addition, according to an embodiment of the present invention, since the ultraviolet protection factor is calculated according to a decision tree of which variables are not only a cosmetic raw material but also sub-information such as a skin type, minimum erythema dose, and the like, there is an advantage that the prediction accuracy is improved. That is, there is an advantage that the prediction accuracy of the ultraviolet protection factor according to the decision tree using the cosmetic raw material and the sub-information as variables is higher than the prediction accuracy of the ultraviolet protection factor according to the decision tree using only the cosmetic raw material as a variable.

### DESCRIPTION OF DRAWINGS

FIG. 1 is a control block diagram of an ultraviolet protection factor calculating apparatus according to an embodiment of the present invention.

FIG. 2 is a flowchart showing an ultraviolet protection factor calculating method of an ultraviolet protection factor calculating apparatus according to an embodiment of the present invention.

FIG. 3 is a flowchart showing a method in which an ultraviolet protection factor calculating apparatus according to an embodiment of the present invention generates a decision tree.

FIG. 4 is an exemplary view of an SPF calculation decision tree generated by an ultraviolet protection factor calculating apparatus according to a first embodiment of the present invention.

FIG. 5 is a graph showing a prediction rate of an SPF calculation decision tree generated according to a first embodiment of the present invention.

FIG. 6 is an exemplary view of an SPF calculation decision tree generated by an ultraviolet protection factor calculating apparatus according to a second embodiment of the present invention.

FIG. 7 is a graph showing a prediction rate of the SPF calculation decision tree generated according to the second embodiment of the present invention.

FIG. 8 is an exemplary view of an SPF calculation decision tree generated by an ultraviolet protection factor calculating apparatus according to a third embodiment of the present invention.

FIG. 9 is a graph showing a prediction rate of the SPF calculation decision tree generated by the ultraviolet protection factor calculating apparatus according to the third embodiment of the present invention.

FIG. 10 is an exemplary view of an SPF calculation decision tree generated by an ultraviolet protection factor calculating apparatus according to a fourth embodiment of the present invention.

FIG. 11 is a graph showing a prediction rate of the SPF calculation decision tree generated by the ultraviolet protection factor calculating apparatus according to the fourth embodiment of the present invention.

FIG. 12 is an exemplary view of an SPF calculation decision tree generated by an ultraviolet protection factor calculating apparatus according to a fifth embodiment of the present invention.

FIG. 13 is a graph showing a prediction rate of the SPF calculation decision tree generated by the ultraviolet protection factor calculating apparatus according to the fifth embodiment of the present invention.

FIG. 14 is an exemplary view of an SPF calculation decision tree generated by an ultraviolet protection factor calculating apparatus according to a sixth embodiment of the present invention.

FIG. 15 is a graph showing a prediction rate of the SPF calculation decision trees generated by the ultraviolet protection factor calculating apparatus according to the sixth embodiment of the present invention.

FIG. 16 is an exemplary view of an SPF calculation decision tree generated by an ultraviolet protection factor calculating apparatus according to a seventh embodiment of the present invention.

FIG. 17 is a graph showing a prediction rate of the SPF calculation decision tree generated by the ultraviolet protection factor calculating apparatus according to the seventh embodiment of the present invention.

FIG. 18 is an exemplary view of a PFA calculation decision tree generated by the ultraviolet protection factor calculating apparatus according to the first embodiment of the present invention.

FIG. 19 is a graph showing a prediction rate of the PFA calculation decision tree generated by the ultraviolet protection factor calculating apparatus according to the first embodiment of the present invention.

FIG. 20 is an exemplary view of a PFA calculation decision tree generated by the ultraviolet protection factor calculating apparatus according to the second embodiment of the present invention.

FIG. 21 is a graph showing a prediction rate of the PFA calculation decision tree generated by the ultraviolet protection factor calculating apparatus according to the second embodiment of the present invention.

FIG. 22 is an exemplary view of a PFA calculation decision tree generated by the ultraviolet protection factor calculating apparatus according to the third embodiment of the present invention.

FIG. 23 is a graph showing a prediction rate of the PFA calculation decision tree generated by the ultraviolet protection factor calculating apparatus according to the third embodiment of the present invention.

FIG. 24 is an exemplary view of a PFA calculation decision tree generated by an ultraviolet protection factor calculating apparatus according to the fourth embodiment of the present invention.

FIG. 25 is a graph showing a prediction rate of the PFA calculation decision tree generated by the ultraviolet protection factor calculating apparatus according to the fourth embodiment of the present invention.

FIG. 26 is an exemplary view of a PFA calculation decision tree generated by the ultraviolet protection factor calculating apparatus according to the fifth embodiment of the present invention.

FIG. 27 is a graph showing a prediction rate of the PFA calculation decision tree generated by the ultraviolet protection factor calculating apparatus according to the fifth embodiment of the present invention.

FIG. 28 is an exemplary view of a PFA calculation decision tree generated by an ultraviolet protection factor calculating apparatus according to the sixth embodiment of the present invention.

FIG. 29 is a graph showing a prediction rate of the PFA calculation decision tree generated by the ultraviolet protection factor calculating apparatus according to the sixth embodiment of the present invention.

FIG. 30 is an exemplary view of a PFA calculation decision tree generated by an ultraviolet protection factor calculating apparatus according to the seventh embodiment of the present invention.

FIG. 31 is a graph showing a prediction rate of the PFA calculation decision tree generated by the ultraviolet protection factor calculating apparatus according to the seventh embodiment of the present invention.

FIG. 32 is an exemplary view showing a method in which an ultraviolet protection factor calculating apparatus according to an embodiment of the present invention outputs an ultraviolet protection factor.

### MODES OF THE INVENTION

Hereinafter, embodiments disclosed herein will be described in detail with reference to the accompanying drawings, but the same or similar components are designated by the same reference numbers regardless of drawing numbers, and duplicate descriptions thereof will be omitted. The suffix “module” or “unit” for components used in the following description is assigned or mixed in consideration of only easiness in writing the specification, and does not have a meaning or a role distinguished from each other in itself

In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

Although the terms “first,” “second,” etc. may be used herein to describe various elements, these elements should not be limited by these terms. These terms are only used to distinguish one element from another.

A singular expression includes a plural expression unless the context clearly refers to otherwise.

In this application, it should be understood that the terms such as “comprise” or “include” are intended to specify the presence of features, integers, steps, operations, elements, components, or combinations thereof disclosed in the specification, but do not preclude the presence or addition of one or more other features, integers, steps, operations, elements, components, or combinations thereof

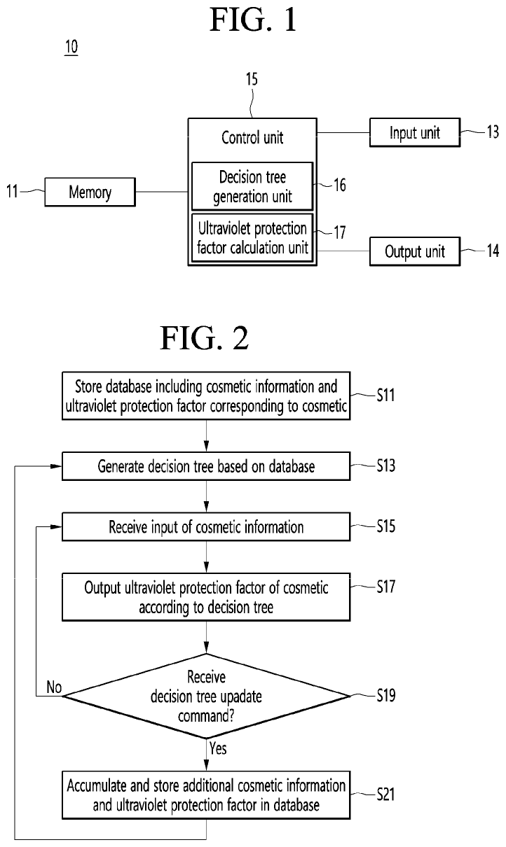

FIG. 1 is a control block diagram of an ultraviolet protection factor calculating apparatus according to an embodiment of the present invention.

An ultraviolet protection factor calculating apparatus 10 according to an embodiment of the present invention may include at least a part or all of a memory 11, an input unit 13, an output unit 14, and a control unit 15, and the control unit 15 may include a decision tree generation unit 16 and an ultraviolet protection factor calculation unit 17.

The memory 11 may store cosmetic information, ultraviolet protection factor information, a decision tree generation algorithm, and generated decision tree information.

The cosmetic information may include cosmetic raw material information for each of a plurality of cosmetics already produced. The memory 11 may map and store ultraviolet protection factor (e.g., SPF, PA, etc.) information on each of cosmetics including cosmetic raw material information (e.g., raw material type, content, manufacturer, product name, etc.). For example, the memory 11 may store first data that maps cosmetic raw material information and an ultraviolet protection factor for a first cosmetic, second data that maps cosmetic raw material information and an ultraviolet protection factor for a second cosmetic, and third data that maps cosmetic raw material information and an ultraviolet protection factor for a third cosmetic.

The present invention may provide an ultraviolet protection factor calculating apparatus and an ultraviolet protection factor calculating method by using cosmetic raw material information and ultraviolet protection factor information for each of a plurality of cosmetics already produced.

The memory 11 may store a database as shown in Table 1.

Hereinafter, Table 1 is an example of a plurality of pieces of cosmetic information stored in the memory 11 and ultraviolet protection factor (e.g., SPF, PA, etc.) information for each of the cosmetic information. In Table 1, only SPF is described as the ultraviolet protection factor, but this is only an example, and thus the present invention is not limited thereto.

TABLE 1

| Cosmetic | Cosmetic raw material | SPF |
|---|---|---|
| First cosmetic | Diethylamino Hydroxybenzoyl | 40 |
| | Hexyl BenzoateTitanium | |
| | DioxideEthylhexyl Methoxycinnamate | |
| Second cosmetic | Diethylamino Hydroxybenzoyl | 130 |
| | Hexyl BenzoateEthylhexyl | |
| | TriazoneZinc Oxide | |
| Third cosmetic | Diethylamino Hydroxybenzoyl Hexyl | 56 |
| | BenzoateEthylhexyl Triazone | |

Meanwhile, according to the embodiment, the cosmetic information may further include sub-information in addition to the cosmetic raw material information for each of a plurality of cosmetics already produced. The memory 11 may map and store ultraviolet protection factor (e.g., SPF, PA, etc.) information on the cosmetic raw material information and at least one piece of sub-information.

Here, the sub-information refers to information on ancillary factors influencing the determination of the ultraviolet protection factor of cosmetics. For example, the sub-information may include a skin type, minimum erythema dose (MED), pigment presence, pigment grade TiO₂ content, product formulation, product type, and the like.

The skin type may refer to a skin type of a test subject in an experiment of measuring the ultraviolet protection factor of the cosmetics. The skin type may be classified according to Fitzpatrick's skin type, and in this case, the skin type may be type 1 which is easily burned but not pigmented, type 2 which is easily burned and induces some pigmentation, type 3 which causes severe burns and induces gradual pigmentation, type 4 which causes slight burns but always induces pigmentation, type 5 which causes almost no burns and induces severe pigmentation, and type 6 which causes no burns and induces pigmentation.

For example, the memory 11 may further store information such as a first skin type (always easily (very badly) reddened, and hardly blackened), a second skin type (easily (severely) reddened, and slightly blackened), a third skin type (normally reddened, and moderately blackened), and a fourth skin type (not so reddened and easily blackened) as sub-information about the skin type.

The minimum erythema amount may refer to a minimum erythema dose of the test subject in the experiment of measuring the ultraviolet protection factor of the cosmetics. Here, the minimum erythema dose may refer to a minimum dose of ultraviolet irradiation that may show erythema in the entire region of the irradiated region within 16 to 24 hours after irradiating ultraviolet ray B to the human skin. For example, the minimum erythema amount may include numerical information such as 29.2 or 36.7. The memory 11 may further store sub-information indicating the minimum erythema dose for each of the cosmetics.

The pigment presence refers to whether or not the cosmetic contains a pigment, for example, and the pigment presence may include information such as yes (included) or no (not included). The memory 11 may further store sub-information indicating the pigment presence for each of the cosmetics.

The pigment grade TiO₂ content refers to a pigment grade TiO₂ content included in the cosmetics, and for example, the pigment grade TiO₂ content may include content information such as 0.15, 2.25, and the like. The memory 11 may further store sub-information indicating the pigment grade TiO₂ content for each of the cosmetics.

The product formulation indicates a state in which a product is made, and may include, for example, water-in-oil (W/O), oil-in-water (O/W), water-in-silicone oil (W/S), and the like. The memory 11 may further store sub-information indicating product formulation for each of the cosmetics.

The product type indicates a shape of a product, and may include, for example, cream, lotion, oil, powder, and the like. The memory 11 may further store sub-information indicating product type for each of the cosmetics.

The memory 11 may store a database as shown in Table 2.

Hereinafter, Table 2 is an example of cosmetic raw material information, skin type information, and ultraviolet protection factor information for each of a plurality of cosmetics stored in the memory 11. In Table 2, only a skin type is described as the sub-information, but this is only an example, and at least one piece of the above-described sub-information may be further included.

TABLE 2

| Cosmetic | Cosmetic raw material | Skin type | SPF |
|---|---|---|---|
| First | Diethylamino Hydroxybenzoyl | 1, YES | 110 |
| cosmetic | Hexyl BenzoateTitanium Dioxide | | |
| Second | Diethylamino Hydroxybenzoyl | 1, NO | 116 |
| cosmetic | Hexyl BenzoateTitanium Dioxide | | |
| Third | Diethylamino Hydroxybenzoyl Hexyl | — | 122 |
| cosmetic | BenzoateEthylhexyl TriazoneTitanium | | |
| | Dioxide | | |
| Fourth | Diethylamino Hydroxybenzoyl Hexyl | 3, YES | 51 |
| cosmetic | BenzoateEthylhexyl TriazoneTitanium | | |
| | Dioxide | | |

Tables 1 and 2 shown above are merely examples for convenience of description, and thus the present invention is not limited thereto. The input unit 13 may receive an input of cosmetic information or an input of an ultraviolet protection factor. The input unit 13 may include a physical key button, or may be formed in a form of a touch screen capable of touch input.

In addition, according to the embodiment, the input unit 13 may further include a communication module (not shown) for receiving cosmetic information or a sensing module (not shown) for sensing cosmetics.

The input unit 13 may directly receive cosmetic raw material information, additional information, or ultraviolet protection factor information for each of the cosmetics from a user. In this case, the user may input cosmetic information through the input unit 13.

The user may input the cosmetic information through the input unit 13 to generate an initial model of the decision tree, perform verification of the decision tree, update the decision tree, or calculate the ultraviolet protection factor.

The input unit 13 may receive cosmetic raw material information, additional information, or ultraviolet protection factor information for each of the cosmetics from a server or a mobile terminal through the communication module. In this case, the input unit 13 may receive cosmetic information from the outside.

In addition, the input unit 13 may acquire at least one cosmetic raw material included in the cosmetic by sensing the cosmetic through the sensing module, acquire sub-information, and directly receive the ultraviolet protection factor information for the sensed cosmetic from the user. In this case, the input unit 13 may receive information of a cosmetic that is a target for calculating the ultraviolet protection factor. That is, the input unit 13 may acquire information on the target cosmetic (e.g., the type and content of the cosmetic raw materials included in the cosmetic) by sensing the target cosmetic that is the target of calculating the ultraviolet protection factor, and the control unit 15 may calculate the ultraviolet protection factor based on the information of the target cosmetic. The control unit 15 may generate the decision tree based on the cosmetic for which the information is input through the input unit 13, or may determine the ultraviolet protection factor by sensing the cosmetic for which the information is input through the input unit 13.

When the cosmetic is sensed, the output unit 14 may output the ultraviolet protection factor by analyzing the cosmetic based on the decision tree.

The output unit 14 may include a display module that visually displays the ultraviolet protection factor, or may include a speaker that audibly displays the ultraviolet protection factor. In addition, the output unit 14 may include the communication module that transmits the ultraviolet protection factor to the server or the mobile terminal.

The control unit 15 may control an operation of the ultraviolet protection factor calculating apparatus. The control unit 15 may control the memory 11, the input unit 13, and the output unit 14, respectively.

In addition, the control unit 15 may generate the decision tree through the decision tree generation unit 16, and may calculate the ultraviolet protection factor through the ultraviolet protection factor calculation unit 17.

The memory 11 may store a cosmetic ultraviolet protection factor database including a plurality of cosmetics already produced and an ultraviolet protection factor corresponding to each of the plurality of cosmetics. The control unit 15 may generate an initial model of an ultraviolet protection factor decision tree (hereinafter, referred to as “decision tree”) based on the stored database.

The decision tree generation unit 16 may generate the decision tree for determining the ultraviolet protection factor according to the cosmetic information based on the data stored in the memory 11.

According to an embodiment, the decision tree generation unit 16 may generate a decision tree that classifies the ultraviolet protection factor according to the cosmetic raw material.

According to another embodiment, the decision tree generation unit 16 may generate a decision tree that classifies the ultraviolet protection factor according to the cosmetic raw material and at least one piece of sub-information.

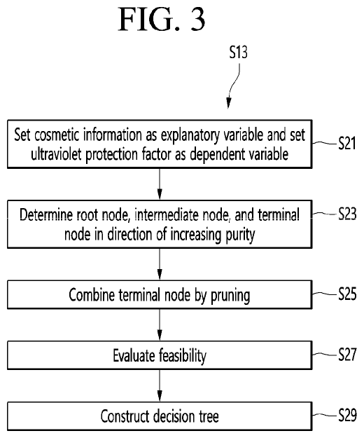

A method of generating the decision tree by the decision tree generation unit 16 will be described in detail in FIGS. 2 and 3.

When cosmetic information is additionally input through the input unit 13 after the initial model of the decision tree is generated, the control unit 15 may control the ultraviolet protection factor calculation unit 17 to determine the ultraviolet protection factor of a cosmetic additionally input based on the decision tree generated through the decision tree generation unit 16.

After determining the ultraviolet protection factor of the additionally input cosmetic, the control unit 15 may add the information of the additionally input cosmetic and the corresponding ultraviolet protection factor to the database stored in the memory 11.

That is, the control unit 15 may determine the ultraviolet protection factor according to the cosmetic information additionally input whenever the information of the cosmetic is additionally input, cumulatively store the information of the determined ultraviolet protection factor in the memory 11 to update the cosmetic ultraviolet protection factor database, and update the decision tree of the initial model based on the updated database.

That is, the control unit 15 may repeat a process of updating the cosmetic ultraviolet protection factor database, determining the ultraviolet protection factor upon additional input of cosmetic information, and updating the decision tree.

As the process of updating the decision tree is repeated, the accuracy of calculating the ultraviolet protection factor may be improved.

[symbol]

FIG. 2 is a flowchart showing an ultraviolet protection factor calculating method of an ultraviolet protection factor calculating apparatus according to an embodiment of the present invention.

The memory 11 of the ultraviolet protection factor calculating apparatus 10 may store a database including cosmetic information and an ultraviolet protection factor corresponding to a cosmetic (S11).

The memory 11 may update a database by receiving additional cosmetic information and the ultraviolet protection factor corresponding to the cosmetic according to a user's request in the database that has already been input.

According to the embodiment, the control unit 15 may further perform verification of additional data when updating the database.

Specifically, when the additional cosmetic information and the ultraviolet protection factor corresponding to the cosmetic are input, the control unit 15 compares the calculated ultraviolet protection factor with the actual ultraviolet protection factor that is additionally input to compare a difference in values by applying only the additional cosmetic information to the already generated decision tree, and when the difference in values is greater than an already set reference value, the control unit 15 may output a message requiring verification. That is, the control unit 15 may allow the user to verify whether the additional input information is correct so that the reliability of the decision tree may be maintained without being updated by the additional incorrect data input.

According to the embodiment, the control unit 15 may exclude the incorrect input value of the cosmetic information and the ultraviolet protection factor corresponding to the cosmetic as already stored in the memory by a user's request. The user's request may be received through the input unit 13.

Here, the cosmetic information may include cosmetic raw material information for each of the above-described cosmetics and sub-information such as a skin type, minimum erythema dose (MED), pigment inclusion, pigment grade TiO₂ content, product formulation, product type, and the like.

The memory 11 may store a database including ultraviolet protection factor information for each of the cosmetics having the cosmetic information. Since the database is the same as described above, a detailed description thereof will be omitted.

The control unit 15 may generate the decision tree based on the database (S13).

The control unit 15 may generate the decision tree by analyzing the cosmetic information stored in the memory 11 and the ultraviolet protection factor information through a decision tree generation unit 16.

FIG. 3 is a flowchart showing a method in which an ultraviolet protection factor calculating apparatus according to an embodiment of the present invention generates a decision tree.

In particular, FIG. 3 may be an example of the flowchart embodying step S13 for generating the decision tree of FIG. 2.

The decision tree generation unit 16 may be composed of a root node, at least one intermediate node, and at least one terminal node, the root node and the intermediate node may include classification criteria of cosmetic information, and the terminal node may generate a decision tree including an ultraviolet protection factor.

First, the decision tree generation unit 16 may set the cosmetic information as an explanatory variable and set the ultraviolet protection factor as a dependent variable (S21).

The decision tree generation unit 16 sets the cosmetic information as the explanatory variable and sets the ultraviolet protection factor as the dependent variable, and then may determine the root node, the intermediate node, and the terminal node in a direction of increasing purity (S23).

Specifically, the decision tree generation unit 16 may determine the root node, the intermediate node, and the terminal node in the direction in which the purity (homogeneity) increases according to the recursive partitioning method.

For example, it will be described on the assumption that the decision tree generation unit 16 determines the root node, the intermediate node, and the terminal node based on the cosmetic raw material information. The decision tree generation unit 16 may sort the cosmetic ultraviolet protection factor database stored in the memory 11 in ascending order according to a content of a specific cosmetic raw material, assume a point between sorted data values as a branch to calculate the Gini coefficient before branching and the Gini coefficient after branching, and examine information gain by calculating a difference between the Gini coefficient before branching and the Gini coefficient after branching. The information gain may refer to the difference between the Gini coefficient before branching and the Gini coefficient after branching.

According to the embodiment, the decision tree generation unit 16 may calculate entropy before branching and entropy after branching instead of the Gini coefficient before branching and the Gini coefficient after branching, and examine the information gain by calculating a difference between entropy before branching and entropy after branching.

In addition, the decision tree generation unit 16 may examine the information gain by calculating various reference values indicating uncertainty such as a p-value of a chi-square statistic in addition to the Gini coefficient and entropy.

The decision tree generation unit 16 may determine the root node, the intermediate node, or the terminal node based on a branch point having the largest information gain. The control unit 15 may determine it as the root node when the branch point is a first branch point, determine it as the terminal node when the branch point has a purity of 100%, and determine it as the intermediate node when the branch point is another branch point that does not correspond to the root node and the terminal node.

When the number of pieces of data is N1 and the number of variables is N2, the decision tree generation unit 16 may determine the root node, the intermediate node, and the terminal node by calculating the uncertainty before branching (e.g., the Gini coefficient or entropy) and the uncertainty after branching for N1×N2 cases and examining the information gain.

The decision tree generation unit 16 may combine the terminal nodes by pruning after determining the root node, the intermediate node, and the terminal node (S25).

After determining the root node, the intermediate node, and the terminal node so that the purity of all the terminal nodes is 100%, the decision tree generation unit 16 may combine the terminal nodes so that overfitting is minimized. Generally, a misclassification rate when new data is added decreases as the number of branch points increases, but when the number of branch points exceeds a predetermined number, the misclassification rate when new data is added may increase, which may be regarded as the overfitting. Therefore, the decision tree generation unit 16 may perform the pruning that combines at least two or more terminal nodes when the number of branch points exceeds a predetermined number. The control unit 15 may perform the pruning according to Equation 1 below.

CC(T)=Err(T)+α×L(T) [Equation 1]

Here, CC(T) is the cost complexity of the decision tree (a value as small as a simple model with few errors but a small number of terminal nodes), Err(T) is a misclassification rate for verification data, L(T) is the number of terminal nodes, and a may refer to a weighted value that combines Err(T) and L(T) and may be a value in a range of 0.01 to 0.01.

The decision tree generation unit 16 may combine the terminal nodes and then perform a feasibility evaluation (S27).

The decision tree generation unit 16 may perform the feasibility evaluation through cross validation by using at least one of a gain chart, a risk chart, and a cost chart.

Specifically, the decision tree generation unit 16 may divide data into k pieces of data based on at least one of the gain chart, the risk chart, and the cost chart, use k-1 pieces of data among the divided k pieces of data as training data, and use one data as test data. The control unit 15 may evaluate the feasibility of the decision tree generated through steps S21, S23, and S25 while changing the training data and the test data.

The decision tree generation unit 16 may construct the decision tree by interpreting analysis results of the decision tree after the feasibility evaluation (S29).

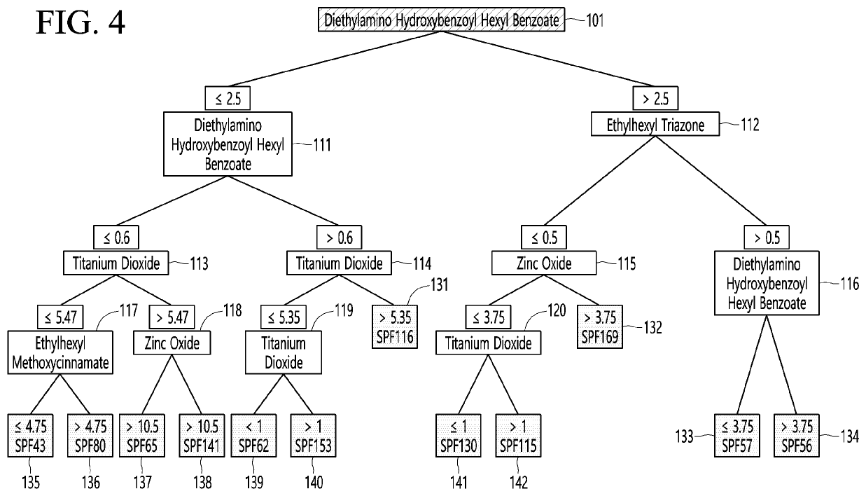

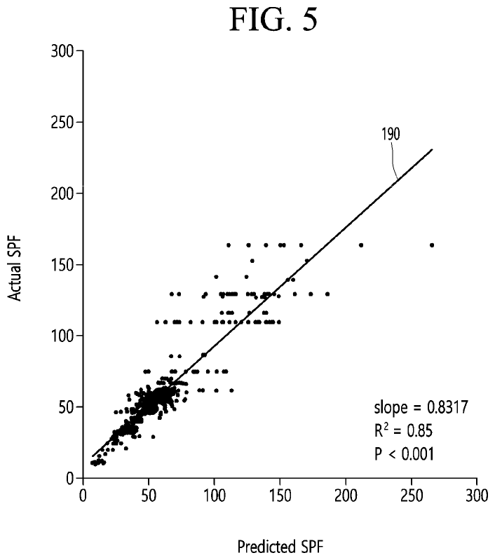

FIG. 4 is an exemplary view of an SPF calculation decision tree generated by an ultraviolet protection factor calculating apparatus according to a first embodiment of the present invention, and FIG. 5 is a graph showing a prediction rate of the SPF calculation decision tree generated according to the first embodiment of the present invention.

According to the first embodiment of the present invention, the decision tree generation unit 16 may generate the decision tree as shown in FIG. 4, wherein the explanatory variable is a cosmetic raw material and the dependent variable is a sun protection factor SPF.

The decision tree according to the first embodiment may include a root node 101, first to tenth intermediate nodes 111 to 120, and first to twelfth terminal nodes 131 to 142. Each of the root node 101 and the first to tenth intermediate nodes 111 to 120 may include a content criterion of the cosmetic raw material, and a child node may be connected from the root node 101 and the first to tenth intermediate nodes 111 to 120, and the child node may be another intermediate node or terminal node.

Referring to the example of FIG. 4, the root node 101 may include a criterion indicating whether the content of Diethylamino hyderoxybenzoyl Hexyl Benzoate, which is a cosmetic raw material is 2.5 g or less or more than 2.5 g, and may be separated into the first intermediate node 111 or the second intermediate node 112 according to the criterion.

The first intermediate node 111 may include a criterion indicating whether the content of Diethylamino hyderoxybenzoyl Hexyl Benzoate is 0.6 g or less or more than 0.6 g, and may be separated into the third intermediate node 113 or the fourth intermediate node 114 according to the criterion.

The fourth intermediate node 114 may include a criterion indicating whether the content of Titanium Dioxide is 5.35 g or less or more than 5.35 g, and may be separated into the ninth intermediate node 119 or the first terminal node 131 according to the criterion.

The ninth intermediate node 119 may include a criterion indicating whether the content of Titanium Dioxide is less than 1 g or more than 1 g, and may be separated into a ninth terminal node 139 or a tenth terminal node 140 according to the criterion.

Some intermediate nodes and some terminal nodes have been described as examples, but other intermediate nodes and other terminal nodes include content criterions similarly to those described above and are separated according to the content criterions, and thus a detailed description thereof will be omitted.

The graph of FIG. 5 may show the SPF prediction rate of the decision tree shown in FIG. 4.

Specifically, in each of the graphs shown in FIG. 5, a horizontal axis is an SPF calculated according to the decision tree (hereinafter referred to as “predicted SPF”), and a vertical axis is an actually measured SPF (hereinafter referred to as “actual SPF”). Therefore, individual points shown in the graph of FIG. 5 may be points displayed at positions corresponding to the SPF calculated according to the decision tree and the actually measured SPF.

A first line 190 shown in the graph of FIG. 5 may be a line connecting an average value of the actual SPF to the predicted SPF. Therefore, a slope of the first line 190 may indicate the prediction accuracy of the decision tree. That is, it may refer that the closer the slope of the first line 190 is to 1, the higher the prediction accuracy of the decision tree.

Referring to FIG. 5, it can be seen that the slope of the first line 190 is 0.8317.

Meanwhile, a deviation of the prediction accuracy (R²) may be calculated through the graph shown in FIG. 5. That is, the average value of the actual SPF and a deviation of the actual SPF may be calculated, and in the case of the graph shown in FIG. 5, it can be seen that the deviation of the prediction accuracy (R²) is 0.85.

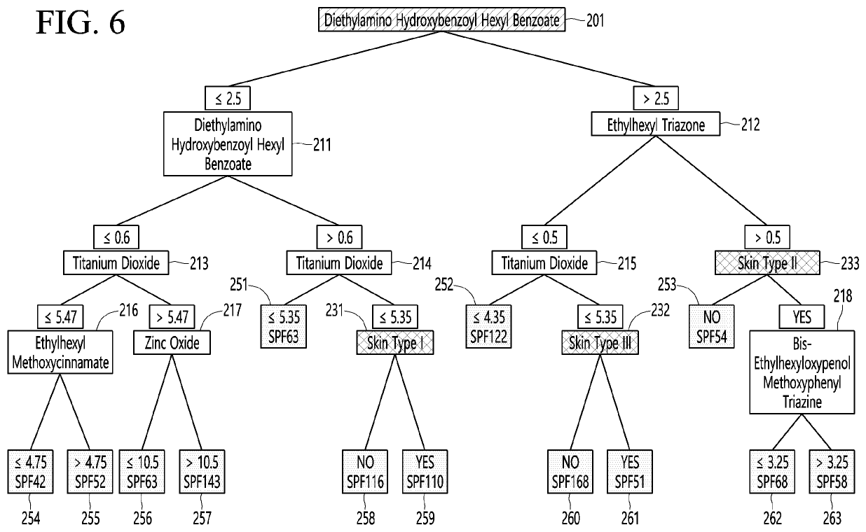

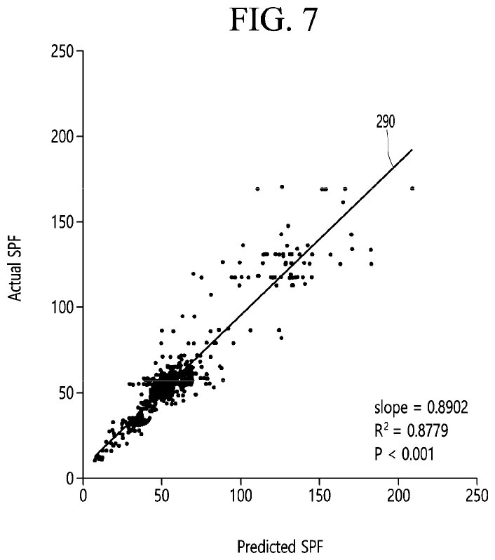

Next, FIG. 6 is an exemplary view of an SPF calculation decision tree generated by an ultraviolet protection factor calculating apparatus according to a second embodiment of the present invention, and FIG. 7 is a graph showing a prediction rate of the SPF calculation decision tree generated according to the second embodiment of the present invention.

According to the second embodiment of the present invention, the decision tree generation unit 16 may generate the decision tree as shown in FIG. 6, wherein the explanatory variable is a cosmetic raw material and a skin type, and the dependent variable is a sun protection factor SPF.

The decision tree according to the second embodiment may include a root node 201, first to eleventh intermediate nodes 211 to 218 and 231 to 233, and first to thirteenth terminal nodes 251 to 263. In the case of the second embodiment, the root node 201 and the first to eighth intermediate nodes 211 to 218 may include the content criterion of the cosmetic raw material, and the ninth to eleventh intermediate nodes 231 to 233 may include the criterion of the skin type. The first to thirteenth terminal nodes 251 to 263 may include the ultraviolet protection factor.

Referring to an example of FIG. 6, the root node 201 may include a criterion indicating whether the content of Diethylamino hyderoxybenzoyl Hexyl Benzoate that is a cosmetic raw material is 2.5 g or less or more than 2.5 g, and may be separated into the first intermediate node 111 or the second intermediate node 112 according to the criterion.

The second intermediate node 212 may include a criterion indicating whether the content of Ethylhexyl Triazone is 0.5 g or less or more than 0.5 g, and may be separated into a fifth intermediate node 215 and a thirteenth intermediate node 233 according to the criterion.

The thirteenth intermediate node 233 may include a criterion indicating whether the skin type is a second type, and may be separated into a third terminal node 253 and an eighth intermediate node 218 according to the criterion.

The eighth intermediate node 218 may be a criterion indicating whether the content of Bis-Ethylhexyloxypenol Methoxyphenyl Triazine is 3.25 g or less or more than 3.25 g, and may be separated into a twelfth terminal node 262 or a thirteenth terminal node 263.

As described above, the decision tree may further include sub-information such as the skin type as well as the cosmetic raw material as the variable for calculating the ultraviolet protection factor.

The graph of FIG. 7 may show the SPF prediction rate of the decision tree shown in FIG. 6.

Hereinafter, the same description as described with reference to FIG. 4 will be omitted.

A second line 290 shown in FIG. 7 is a line connecting an average value of the actual SPF to the predicted SPF, and a slope of the second line 290 indicating prediction accuracy may be 0.8902.

Meanwhile, in the case of the graph shown in FIG. 7, the deviation of the prediction accuracy (R²) may be 0.8779.

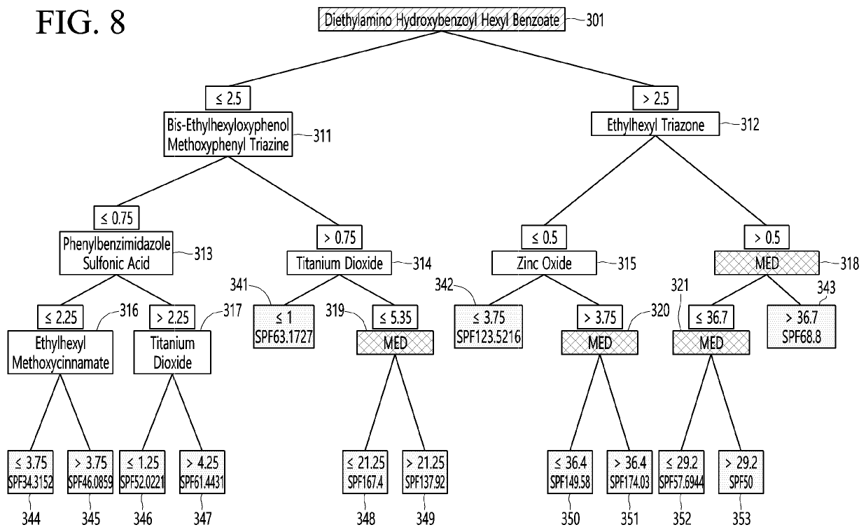

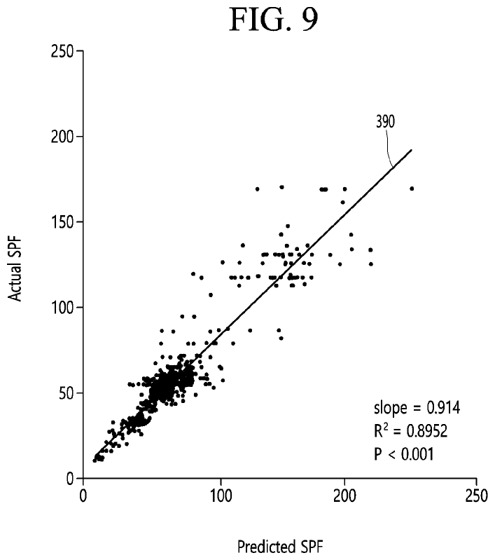

FIG. 8 is an exemplary view of an SPF calculation decision tree generated by an ultraviolet protection factor calculating apparatus according to a third embodiment of the present invention, and FIG. 9 is a graph showing a prediction rate of the SPF calculation decision tree generated by the ultraviolet protection factor calculating apparatus according to the third embodiment of the present invention.

According to the third embodiment of the present invention, the decision tree generation unit 16 may generate the decision tree as shown in FIG. 8, wherein the explanatory variable is a cosmetic raw material and minimum erythema dose (MED), and the dependent variable is a sun protection factor SPF.

According to the third embodiment, the decision tree may include a root node 301, first to eleventh intermediate nodes 311 to 317 and 318 to 321, and first to thirteenth terminal nodes 341 to 353. In the case of the third embodiment, the root node 301 and the first to seventh intermediate nodes 311 to 317 may include the content criterion of the cosmetic raw material, and the eighth to eleventh intermediate nodes 318 to 321 may include the criterion of the minimum erythema dose. The first to thirteenth terminal nodes 341 to 353 may include the ultraviolet protection factor.

As described above, the SPF calculation decision tree according to the third embodiment of the present invention may further include sub-information such as the minimum erythema and the cosmetic raw material as the variable for calculating the ultraviolet protection factor.

The graph of FIG. 9 shows the prediction rate of the SPF calculation decision tree shown in FIG. 8, and a third line 390 shown in FIG. 9 may be a line connecting an average value of the actual SPF to the predicted SPF. As shown in FIG. 9, it can be seen that a slope of the third line 390 indicating the prediction accuracy of the SPF calculation decision tree according to the third embodiment is 0.914, and the deviation of prediction accuracy (R²) is 0.8952.

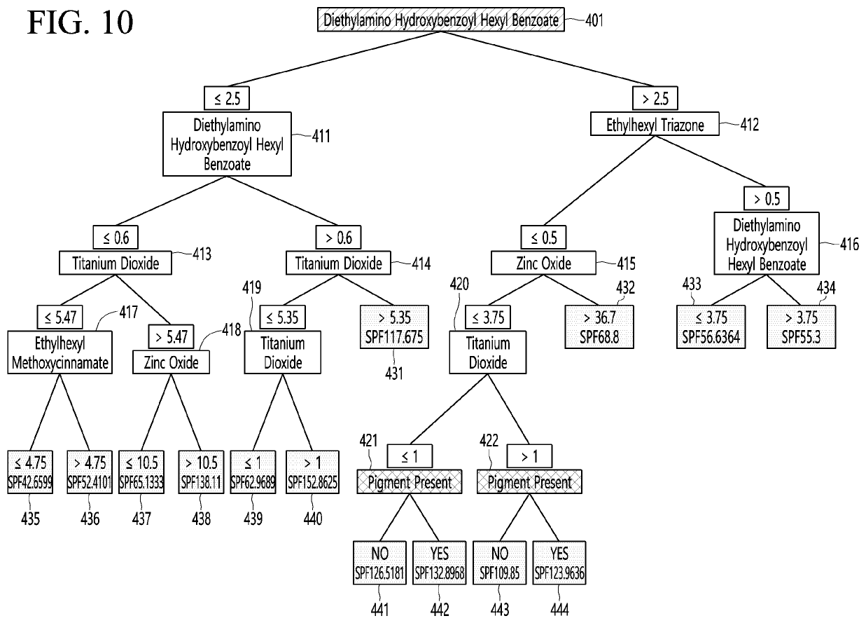

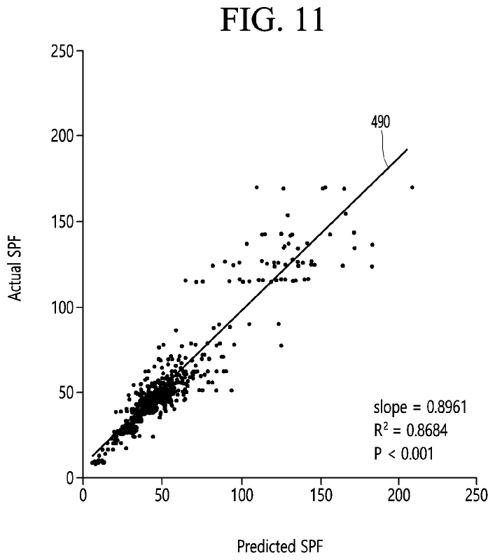

FIG. 10 is an exemplary view of an SPF calculation decision tree generated by an ultraviolet protection factor calculating apparatus according to a fourth embodiment of the present invention, and FIG. 11 is a graph showing a prediction rate of the SPF calculation decision tree generated by the ultraviolet protection factor calculating apparatus according to the fourth embodiment of the present invention.

According to the fourth embodiment of the present invention, the decision tree generation unit 16 may generate the decision tree as shown in FIG. 10, wherein the explanatory variable is a cosmetic raw material and pigment presence, and the dependent variable is a sun protection factor SPF.

According to the fourth embodiment, the decision tree may include a root node 401, first to twelfth intermediate nodes 411 to 420 and 421 to 422, and first to fourteenth terminal nodes 431 to 444. In the case of the fourth embodiment, the root node 401 and the first to tenth intermediate nodes 411 to 420 may include the content criterion of the cosmetic raw material, and the eleventh to twelfth intermediate nodes 421 to 422 may include the criterion indicating the pigment presence. The first to fourth terminal nodes 431 to 444 may include the sun protection factor SPF.

As described above, the SPF calculation decision tree according to the fourth embodiment of the present invention may further include sub-information such as the pigment presence as well as the cosmetic raw material as the variable for calculating the ultraviolet protection factor.

The graph of FIG. 11 shows the prediction rate of the SPF calculation decision tree shown in FIG. 10, and a fourth line 490 shown in FIG. 11 may be a line connecting an average value of the actual SPF to the predicted SPF. As shown in FIG. 11, it can be seen that a slope of the fourth line 490 indicating the prediction accuracy of the SPF calculation decision tree according to the fourth embodiment is 0.8961, and the deviation of prediction accuracy (R²) is 0.8654.

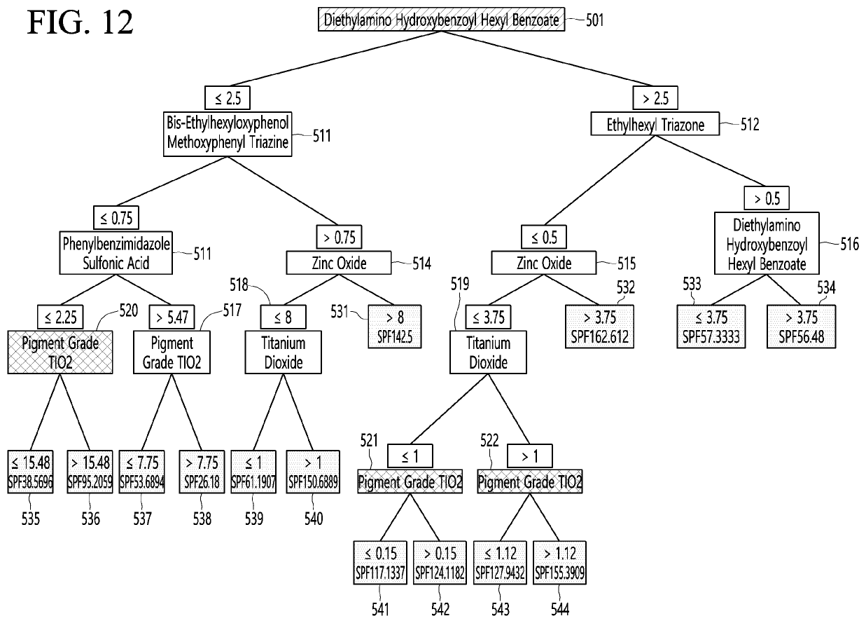

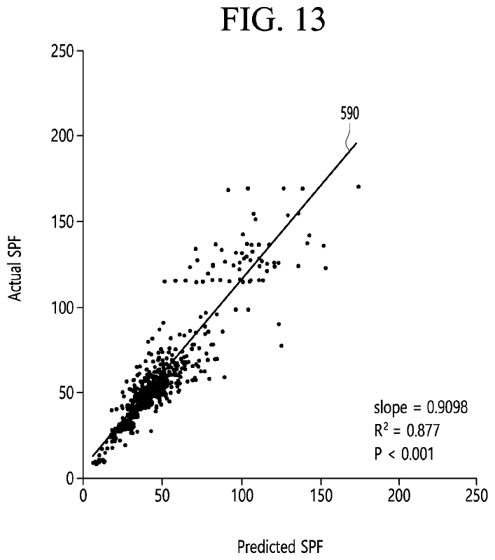

FIG. 12 is an exemplary view of an SPF calculation decision tree generated by an ultraviolet protection factor calculating apparatus according to a fifth embodiment of the present invention, and FIG. 13 is a graph showing a prediction rate of the SPF calculation decision tree generated by the ultraviolet protection factor calculating apparatus according to the fifth embodiment of the present invention.

According to the fifth embodiment of the present invention, the decision tree generation unit 16 may generate the decision tree as shown in FIG. 12, wherein the explanatory variable is a cosmetic raw material and pigment grade TiO₂ content, and the dependent variable is a sun protection factor SPF.

According to the fifth embodiment, the decision tree may include a root node 501, first to twelfth intermediate nodes 511 to 522, and first to fourteenth terminal nodes 431 to 444. In the case of the fifth embodiment, the root node 501 and the first to ninth intermediate nodes 511 to 519 may include the content criterion of the cosmetic raw material, and the tenth to twelfth intermediate nodes 520 to 522 may include the criterion indicating the pigment grade TiO₂ content. The first to fourth terminal nodes 431 to 444 may include the sun protection factor SPF.

As described above, the SPF calculation decision tree according to the fifth embodiment of the present invention may further include sub-information such as the pigment grade TiO₂ content as well as the cosmetic raw material as the variable for calculating the ultraviolet protection factor.

The graph of FIG. 13 shows the prediction rate of the SPF calculation decision tree shown in FIG. 12, and a fifth line 590 shown in FIG. 13 may be a line connecting an average value of the actual SPF to the predicted SPF. As shown in FIG. 13, it can be seen that a slope of the fifth line 590 indicating the prediction accuracy of the SPF calculation decision tree according to the fifth embodiment is 0.9098, and the deviation of prediction accuracy (R²) is 0.877.

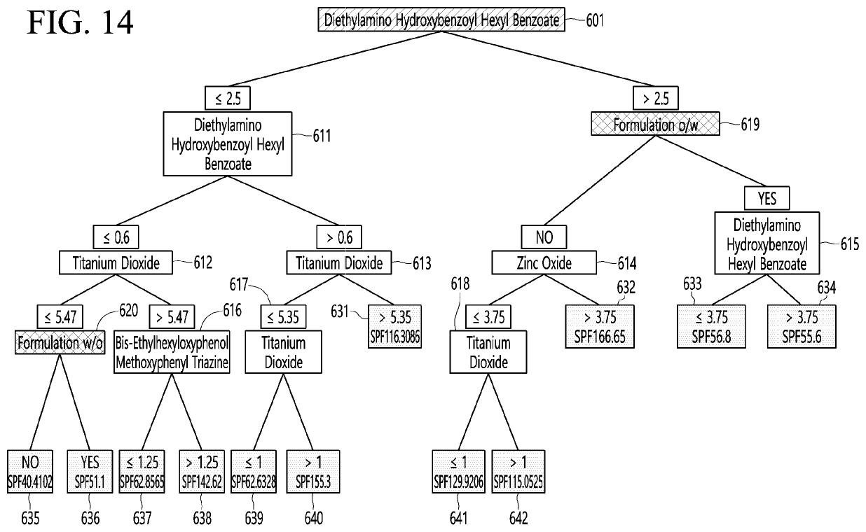

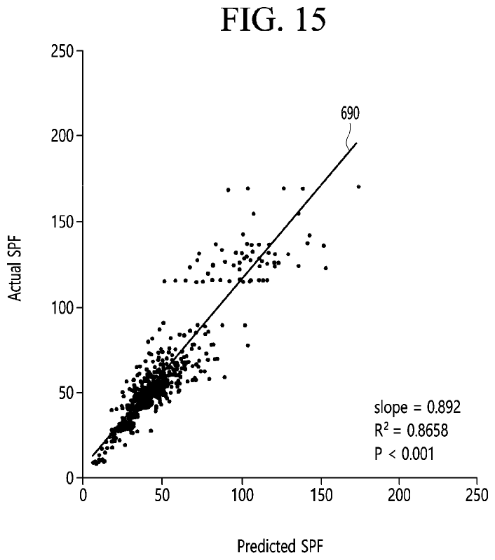

FIG. 14 is an exemplary view of an SPF calculation decision tree generated by an ultraviolet protection factor calculating apparatus according to a sixth embodiment of the present invention, and FIG. 15 is a graph showing a prediction rate of the SPF calculation decision tree generated by the ultraviolet protection factor calculating apparatus according to the sixth embodiment of the present invention.

According to the sixth embodiment of the present invention, the decision tree generation unit 16 may generate the decision tree as shown in FIG. 14, wherein the explanatory variable is a cosmetic raw material and product formation, and the dependent variable is a sun protection factor SPF.

According to the sixth embodiment, the decision tree may include a root node 601, first to tenth intermediate nodes 611 to 620, and first to twelfth terminal nodes 631 to 642. In the case of the sixth embodiment, the root node 601 and the first to eighth intermediate nodes 611 to 618 may include the content criterion of the cosmetic raw material, and the ninth to tenth intermediate nodes 619 to 620 may include the criterion indicating the product formulation. The first to twelfth terminal nodes 631 to 642 may include the sun protection factor SPF.

As described above, the SPF calculation decision tree according to the sixth embodiment of the present invention may further include sub-information such as the product formulation as well as the cosmetic raw material as the variable for calculating the ultraviolet protection factor.

The graph of FIG. 15 shows the prediction rate of the SPF calculation decision tree shown in FIG. 14, and a sixth line 690 shown in FIG. 15 may be a line connecting an average value of the actual SPF to the predicted SPF. As shown in FIG. 15, it can be seen that a slope of the sixth line 690 indicating the prediction accuracy of the SPF calculation decision tree according to the sixth embodiment is 0.892, and the deviation of prediction accuracy (R²) is 0.8658.

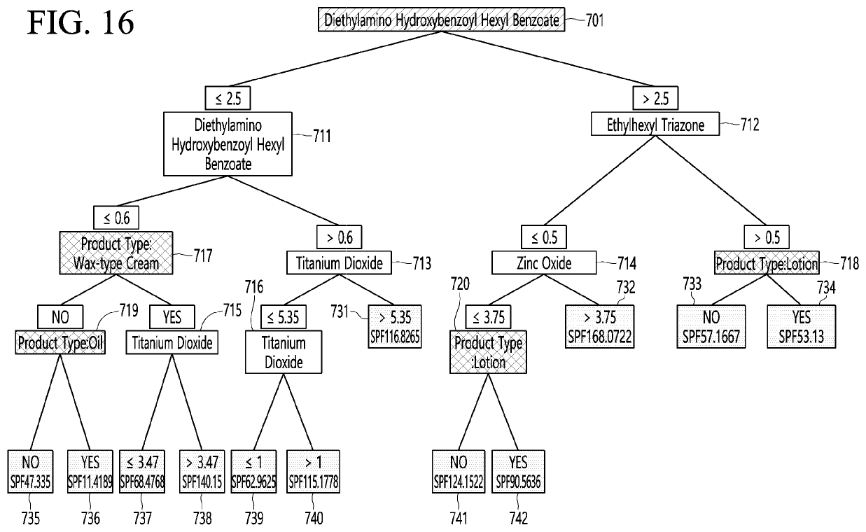

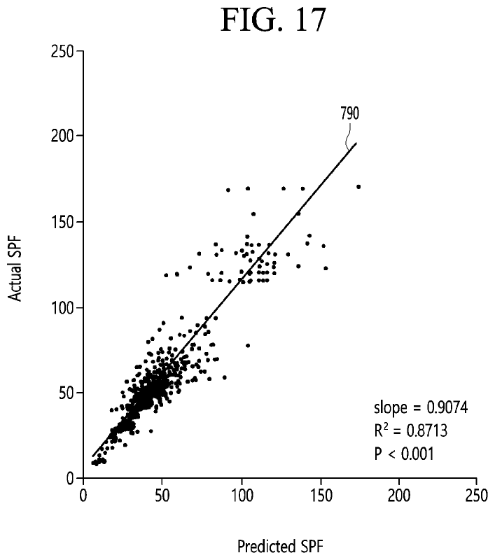

FIG. 16 is an exemplary view of an SPF calculation decision tree generated by an ultraviolet protection factor calculating apparatus according to a seventh embodiment of the present invention, and FIG. 17 is a graph showing a prediction rate of the SPF calculation decision tree generated by the ultraviolet protection factor calculating apparatus according to the seventh embodiment of the present invention.

According to the seventh embodiment of the present invention, the decision tree generation unit 16 may generate the decision tree as shown in FIG. 16, wherein the explanatory variable is a cosmetic raw material and a product type, and the dependent variable is a sun protection factor SPF.

According to the seventh embodiment, the decision tree may include a root node 701, first to tenth intermediate nodes 711 to 720, and first to twelfth terminal nodes 731 to 742. In the case of the seventh embodiment, the root node 701 and the first to sixth intermediate nodes 711 to 716 may include the content criterion of the cosmetic raw material, and the seventh to tenth intermediate nodes 717 to 720 may include the criterion indicating the product type. The first to twelfth terminal nodes 731 to 742 may include the sun protection factor SPF.

As described above, the SPF calculation decision tree according to the seventh embodiment of the present invention may further include sub-information such as the product type as well as the cosmetic raw material as the variable for calculating the ultraviolet protection factor.

The graph of FIG. 17 shows the prediction rate of the SPF calculation decision tree shown in FIG. 16, and a seventh line 790 shown in FIG. 17 may be a line connecting an average value of the actual SPF to the predicted SPF. As shown in FIG. 17, it can be seen that a slope of the seventh line 790 indicating the prediction accuracy of the SPF calculation decision tree according to the seventh embodiment is 0.9074, and the deviation of prediction accuracy (R²) is 0.8713.

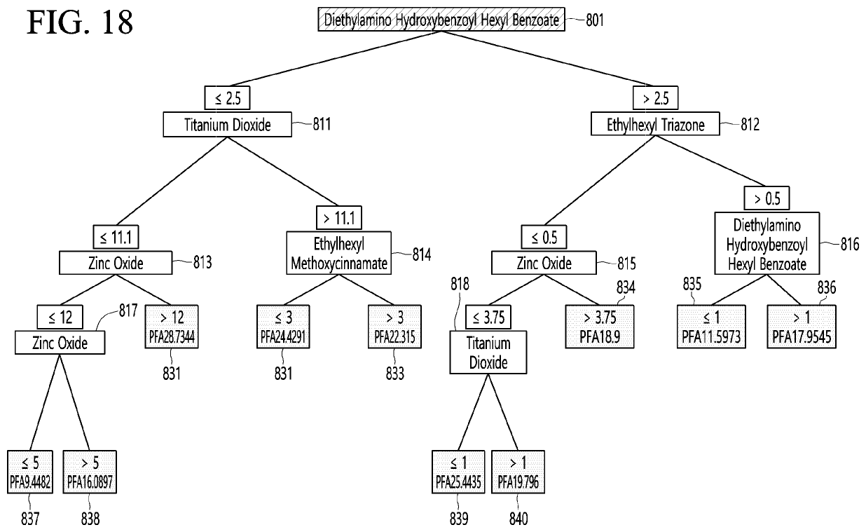

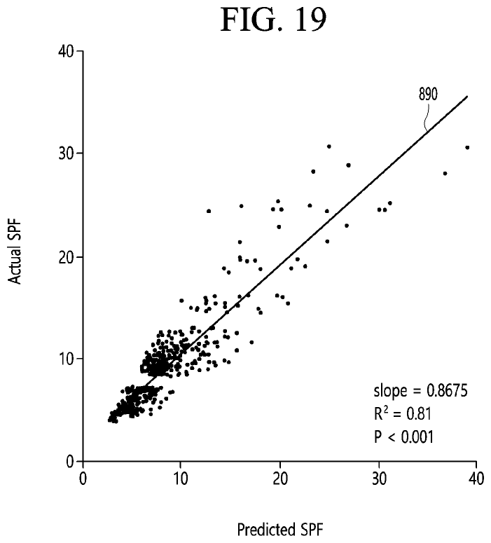

FIG. 18 is an exemplary view of a PFA calculation decision tree generated by the ultraviolet protection factor calculating apparatus according to the first embodiment of the present invention, and FIG. 19 is a graph showing a prediction rate of the PFA calculation decision tree generated by the ultraviolet protection factor calculating apparatus according to the first embodiment of the present invention.

According to the first embodiment of the present invention, the decision tree generation unit 16 may generate the decision tree as shown in FIG. 18, wherein the explanatory variable is a cosmetic raw material and the dependent variable is an ultraviolet protection factor PFA.

According to the first embodiment, the decision tree may include a root node 801, first to eighth intermediate nodes 811 to 818, and first to tenth terminal nodes 831 to 840. In the case of the first embodiment, the root node 801 and the first to eighth intermediate nodes 811 to 818 may include the content criterion of the cosmetic raw material. The first to tenth terminal nodes 831 to 840 may include the ultraviolet protection factor PFA.

As described above, the PFA calculation decision tree according to the first embodiment of the present invention may include only the cosmetic raw material as the variable for calculating the ultraviolet protection factor.

The graph of FIG. 19 shows the prediction rate of the PFA calculation decision tree shown in FIG. 18, and an eighth line 890 shown in FIG. 18 may be a line connecting an average value of the actual PFA to the predicted PFA. As shown in FIG. 18, it can be seen that a slope of the eighth line 890 indicating the prediction accuracy of the PFA calculation decision tree according to the first embodiment is 0.8675, and the deviation of prediction accuracy (R²) is 0.81.

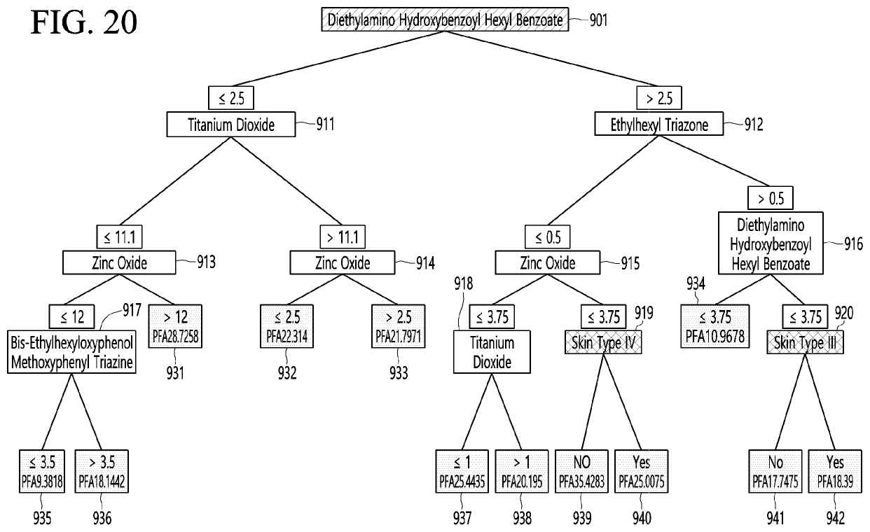

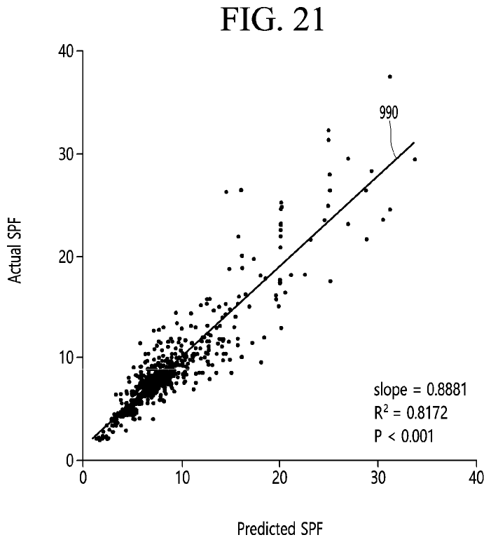

FIG. 20 is an exemplary view of a PFA calculation decision tree generated by the ultraviolet protection factor calculating apparatus according to the second embodiment of the present invention, and FIG. 21 is a graph showing a prediction rate of the PFA calculation decision tree generated by the ultraviolet protection factor calculating apparatus according to the second embodiment of the present invention.

According to the second embodiment of the present invention, the decision tree generation unit 16 may generate the decision tree as shown in FIG. 20, wherein the explanatory variable is a cosmetic raw material and a skin type, and the dependent variable is an ultraviolet protection factor PFA.

According to the second embodiment, the decision tree may include a root node 901, first to tenth intermediate nodes 911 to 920, and first to twelfth terminal nodes 931 to 942. In the case of the second embodiment, the root node 901 and the first to eighth intermediate nodes 911 to 918 may include the content criterion of the cosmetic raw material, and the ninth to tenth intermediate nodes 919 to 920 may include the criterion indicating the skin type. The first to twelfth terminal nodes 931 to 942 may include the ultraviolet protection factor PFA.

As described above, the PFA calculation decision tree according to the second embodiment of the present invention may include sub-information such as the cosmetic raw material and the skin type as the variable for calculating the ultraviolet protection factor.

The graph of FIG. 21 shows the prediction rate of the PFA calculation decision tree shown in FIG. 20, and a ninth line 990 shown in FIG. 21 may be a line connecting an average value of the actual PFA to the predicted PFA. As shown in FIG. 21, it can be seen that a slope of the ninth line 990 indicating the prediction accuracy of the PFA calculation decision tree according to the second embodiment is 0.8881, and the deviation of prediction accuracy (R²) is 0.8172.

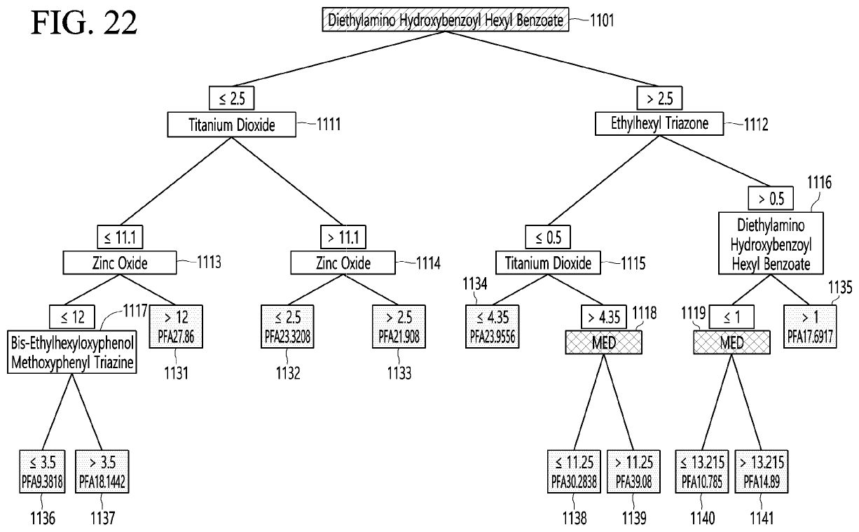

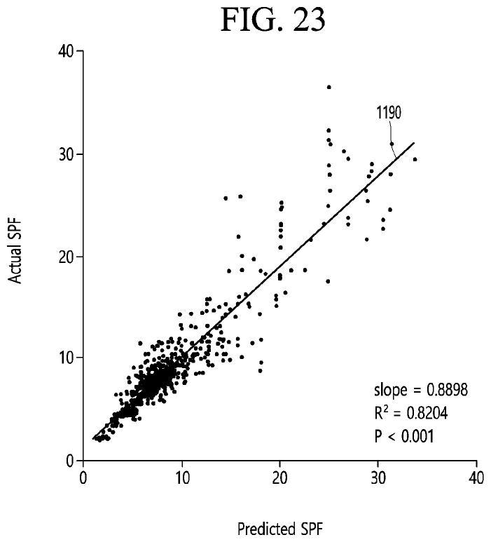

FIG. 22 is an exemplary view of a PFA calculation decision tree generated by the ultraviolet protection factor calculating apparatus according to the third embodiment of the present invention, and FIG. 23 is a graph showing a prediction rate of the PFA calculation decision tree generated by the ultraviolet protection factor calculating apparatus according to the third embodiment of the present invention.

According to the third embodiment of the present invention, the decision tree generation unit 16 may generate the decision tree as shown in FIG. 22, wherein the explanatory variable is a cosmetic raw material and minimum erythema dose (MED), and the dependent variable is an ultraviolet protection factor PFA.

According to the third embodiment, the decision tree may include a root node 1101, first to ninth intermediate nodes 1111 to 1119, and first to eleventh terminal nodes 1131 to 1141. In the case of the third embodiment, the root node 1101 and the first to seventh intermediate nodes 1111 to 1117 may include the content criterion of the cosmetic raw material, and the eighth to ninth intermediate nodes 1118 to 1119 may include the criterion indicating the minimum erythema. The first to eleventh terminal nodes 1131 to 1141 may include the ultraviolet protection factor PFA.

As described above, the PFA calculation decision tree according to the third embodiment of the present invention may include sub-information such as the cosmetic raw material and the minimum erythema dose as the variable for calculating the ultraviolet protection factor.

The graph of FIG. 23 shows the prediction rate of the PFA calculation decision tree shown in FIG. 22, and a tenth line 1190 shown in FIG. 23 may be a line connecting an average value of the actual PFA to the predicted PFA. As shown in FIG. 23, it can be seen that a slope of the tenth line 1190 indicating the prediction accuracy of the PFA calculation decision tree according to the third embodiment is 0.8892, and the deviation of prediction accuracy (R²) is 0.8204.

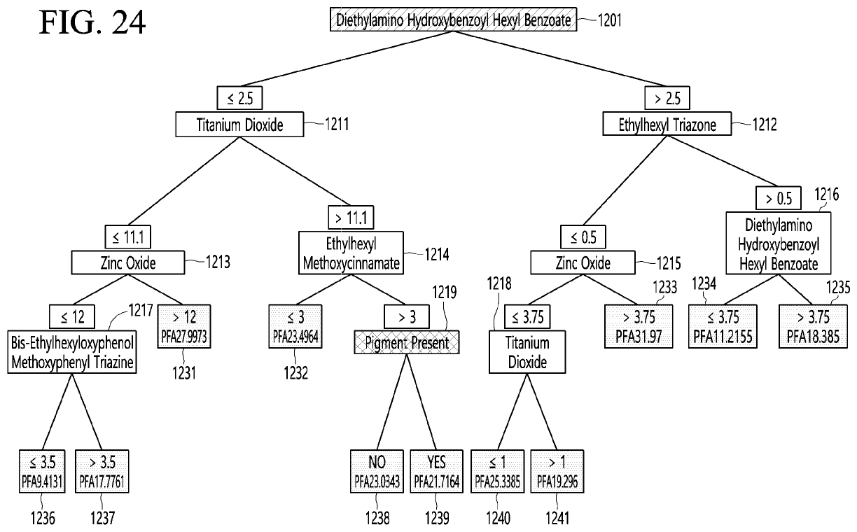

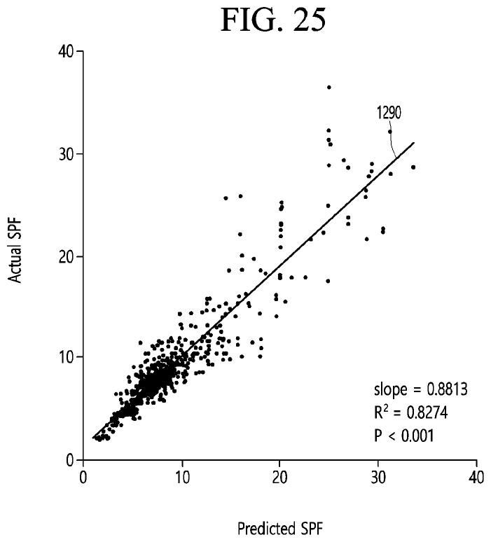

FIG. 24 is an exemplary view of a PFA calculation decision tree generated by the ultraviolet protection factor calculating apparatus according to the fourth embodiment of the present invention, and FIG. 25 is a graph showing a prediction rate of the PFA calculation decision tree generated by the ultraviolet protection factor calculating apparatus according to the fourth embodiment of the present invention.

According to the fourth embodiment of the present invention, the decision tree generation unit 16 may generate the decision tree as shown in FIG. 24, wherein the explanatory variable is a cosmetic raw material and pigment presence, and the dependent variable is an ultraviolet protection factor PFA.

According to the fourth embodiment, the decision tree may include a root node 1201, first to ninth intermediate nodes 1211 to 1219, and first to eleventh terminal nodes 1231 to 1441. In the case of the fourth embodiment, the root node 1201 and the first to eighth intermediate nodes 1211 to 1218 may include the content criterion of the cosmetic raw material, and the ninth intermediate node 1219 may include the criterion indicating the pigment presence. The first to eleventh terminal nodes 1231 to 1241 may include the ultraviolet protection factor PFA.

As described above, the PFA calculation decision tree according to the fourth embodiment of the present invention may include sub-information such as the cosmetic raw material and the pigment presence as the variable for calculating the ultraviolet protection factor.

The graph of FIG. 25 shows the prediction rate of the PFA calculation decision tree shown in FIG. 24, and an eleventh line 1290 shown in FIG. 25 may be a line connecting an average value of the actual PFA to the predicted PFA. As shown in FIG. 25, it can be seen that a slope of the eleventh line 1290 indicating the prediction accuracy of the PFA calculation decision tree according to the fourth embodiment is 0.8813, and the deviation of prediction accuracy (R²) is 0.8274.

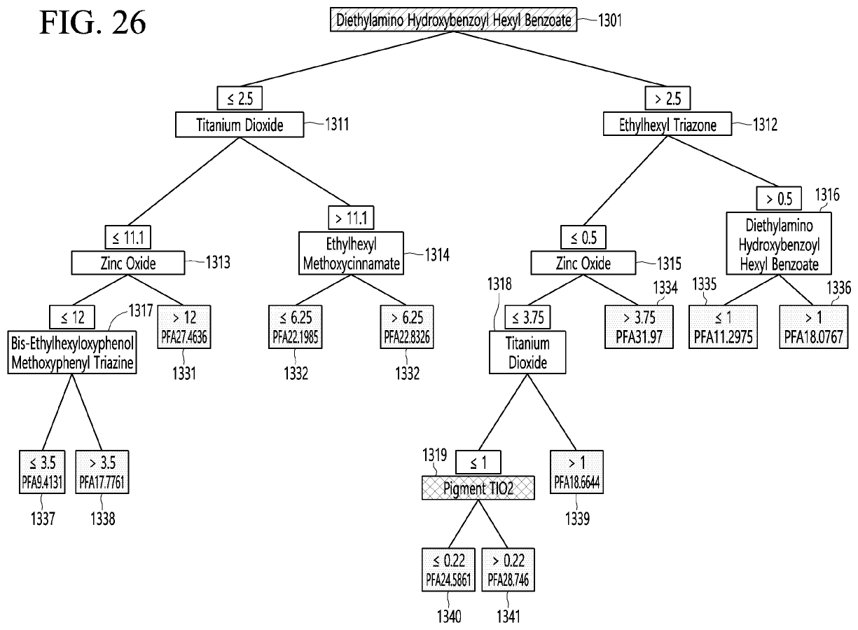

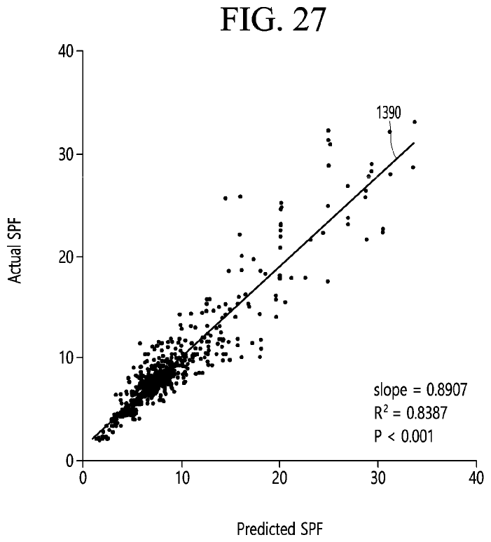

FIG. 26 is an exemplary view of a PFA calculation decision tree generated by the ultraviolet protection factor calculating apparatus according to the fifth embodiment of the present invention, and FIG. 27 is a graph showing a prediction rate of the PFA calculation decision tree generated by the ultraviolet protection factor calculating apparatus according to the fifth embodiment of the present invention.

According to the fifth embodiment of the present invention, the decision tree generation unit 16 may generate the decision tree as shown in FIG. 26, wherein the explanatory variable is a cosmetic raw material and pigment grade TiO₂ content, and the dependent variable is an ultraviolet protection factor PFA.

According to the fifth embodiment, the decision tree may include a root node 1301, first to ninth intermediate nodes 1311 to 1319, and first to eleventh terminal nodes 1331 to 1341. In the case of the fifth embodiment, the root node 1301 and the first to eighth intermediate nodes 1311 to 1318 may include the content criterion of the cosmetic raw material, and the ninth intermediate node 1319 may include the criterion indicating the pigment grade TiO₂ content. The first to eleventh terminal nodes 1331 to 1341 may include the ultraviolet protection factor PFA.

As described above, the PFA calculation decision tree according to the fifth embodiment of the present invention may include sub-information such as the cosmetic raw material and the pigment grade TiO₂ content as the variable for calculating the ultraviolet protection factor.

The graph of FIG. 27 shows the prediction rate of the PFA calculation decision tree shown in FIG. 26, and a twelfth line 1390 shown in FIG. 27 may be a line connecting an average value of the actual PFA to the predicted PFA. As shown in FIG. 27, it can be seen that a slope of the twelfth line 1390 indicating the prediction accuracy of the PFA calculation decision tree according to the fifth embodiment is 0.8907, and the deviation of prediction accuracy (R²) is 0.8387.

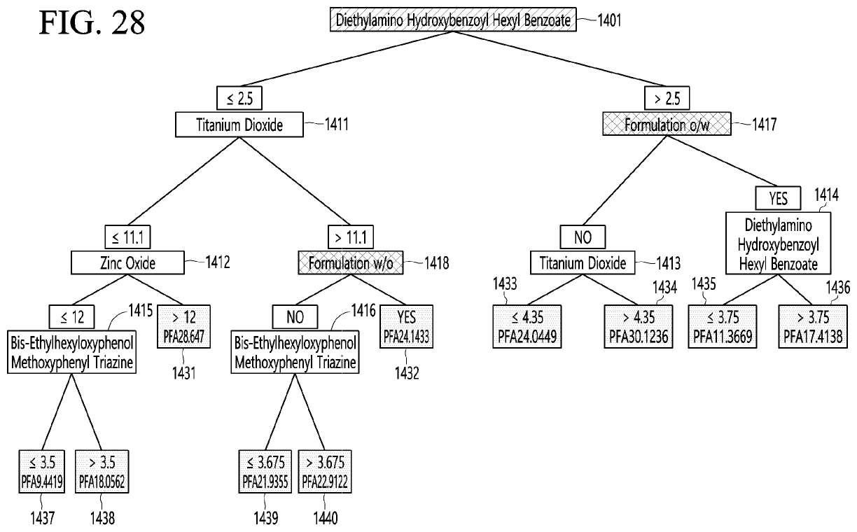

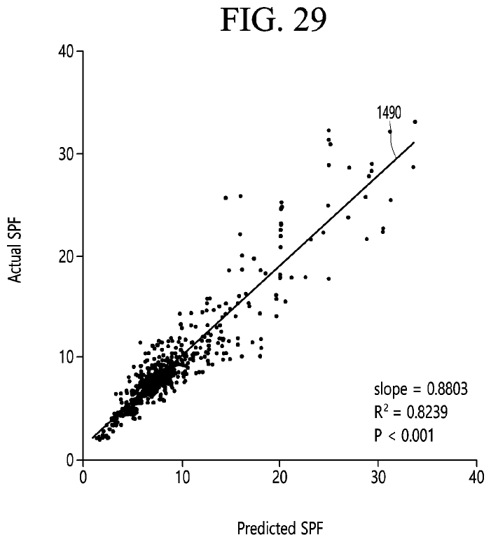

FIG. 28 is an exemplary view of a PFA calculation decision tree generated by the ultraviolet protection factor calculating apparatus according to the sixth embodiment of the present invention, and FIG. 29 is a graph showing a prediction rate of the PFA calculation decision tree generated by the ultraviolet protection factor calculating apparatus according to the sixth embodiment of the present invention.

According to the sixth embodiment of the present invention, the decision tree generation unit 16 may generate the decision tree as shown in FIG. 28, wherein the explanatory variable is a cosmetic raw material and product formulation, and the dependent variable is an ultraviolet protection factor PFA.

According to the sixth embodiment, the decision tree may include a root node 1401, first to eighth intermediate nodes 1411 to 1418, and first to tenth terminal nodes 1431 to 1440. In the case of the sixth embodiment, the root node 1401 and the first to sixth intermediate nodes 1411 to 1416 may include the content criterion of the cosmetic raw material, and the seventh to eighth intermediate nodes 1417 to 1418 may include the criterion indicating the product formulation. The first to tenth terminal nodes 1431 to 1440 may include the ultraviolet protection factor PFA.

As described above, the PFA calculation decision tree according to the sixth embodiment of the present invention may include sub-information such as the cosmetic raw material and the product formulation as the variable for calculating the ultraviolet protection.

The graph of FIG. 29 shows the prediction rate of the PFA calculation decision tree shown in FIG. 28, and a thirteenth line 1490 shown in FIG. 29 may be a line connecting an average value of the actual PFA to the predicted PFA. As shown in FIG. 29, it can be seen that a slope of the thirteenth line 1490 indicating the prediction accuracy of the PFA calculation decision tree according to the sixth embodiment is 0.8803, and the deviation of the prediction accuracy (R²) is 0.8239.

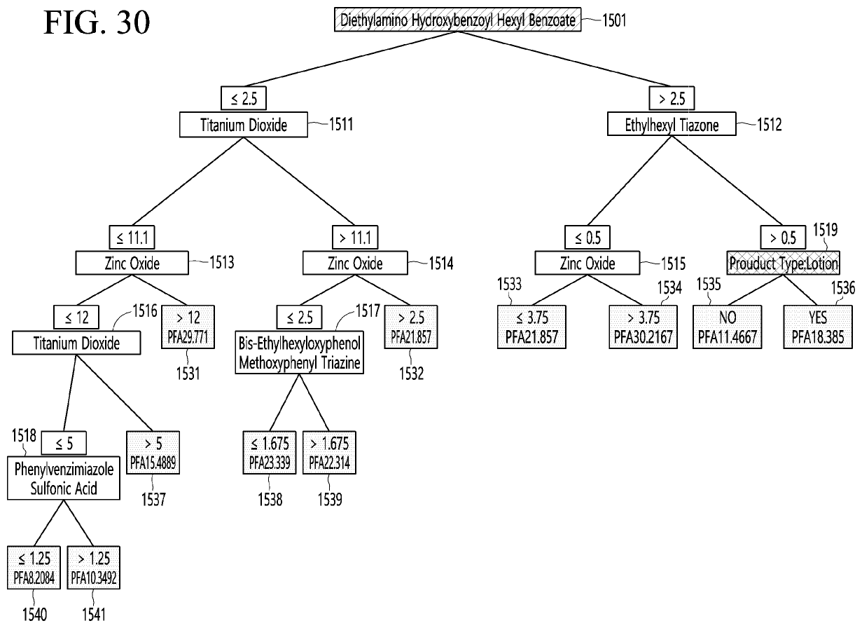

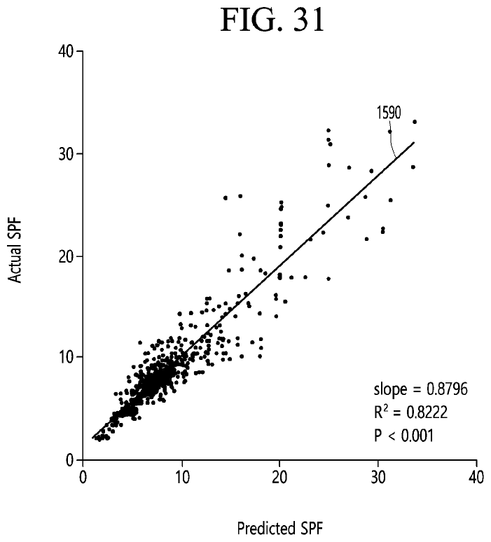

FIG. 30 is an exemplary view of a PFA calculation decision tree generated by an ultraviolet protection factor calculating apparatus according to the seventh embodiment of the present invention, and FIG. 31 is a graph showing a prediction rate of the PFA calculation decision tree generated by the ultraviolet protection factor calculating apparatus according to the seventh embodiment of the present invention.

According to the seventh embodiment of the present invention, the decision tree generation unit 16 may generate the decision tree as shown in FIG. 30, wherein the explanatory variable is a cosmetic raw material and a product type, and the dependent variable is an ultraviolet protection factor PFA.

According to the seventh embodiment, the decision tree may include a root node 1501, first to ninth intermediate nodes 1511 to 1519, and first to eleventh terminal nodes 1531 to 1541. In the case of the seventh embodiment, the root node 1501 and the first to eighth intermediate nodes 1511 to 1518 may include the content criterion of the cosmetic raw material, and the ninth intermediate node 1519 may include the criterion indicating the product type. The first to eleventh terminal nodes 1531 to 1541 may include the ultraviolet protection factor PFA.

As described above, the PFA calculation decision tree according to the seventh embodiment of the present invention may include sub-information such as the cosmetic raw material and the product type as the variable for calculating the ultraviolet protection factor.

The graph of FIG. 31 shows the prediction rate of the PFA calculation decision tree shown in FIG. 30, and a fourteenth line 1590 shown in FIG. 31 may be a line connecting an average value of the actual PFA to the predicted PFA. As shown in FIG. 31, it can be seen that a slope of the fourteenth line 1590 indicating the prediction accuracy of the PFA calculation decision tree according to the seventh embodiment is 0.8796, and the deviation of the prediction accuracy (R²) is 0.8222.

Referring to the SPF calculation decision tree according to the first to seventh embodiments through FIGS. 4 to 17, the prediction accuracy is 0.8317 when the calculation variable is only cosmetic raw material, the prediction accuracy is 0.8902, 0.914, 0.8961, 0.9098, 0.892 or 0.9074 when the calculation variable includes sub-information in addition to the cosmetic raw material, and the prediction accuracy is higher when there are two calculation variables than when there is one calculation variable.

Similarly, referring to the PFA calculation decision tree according to the first to seventh embodiments through FIGS. 18 to 31, the prediction accuracy is 0.8675 when the calculation variable is only cosmetic raw material, the prediction accuracy is 0.8881, 0.8898, 0.8813, 0.8907, 0.8803, or 0.8796 when the calculation variable includes sub-information in addition to the cosmetic raw material, and the prediction accuracy is higher when there are two calculation variables than when there is one calculation variable.

That is, according to the embodiment of the present invention, it can be seen that the deviation of the decision tree is higher and the prediction accuracy is higher when the explanatory variable further includes sub-information in addition to cosmetic raw material than when the explanatory variable is only the cosmetic raw material.

In the present invention, only one or two calculation variables have been described as an example, but the decision tree generation unit 16 may generate a decision tree having three or more calculation variables, and there is an advantage that the larger the number of calculation variables, the better the prediction accuracy of the ultraviolet protection factor.

Again, FIG. 2 will be described.

The control unit 15 may determine whether the input of the cosmetic information is received (S15).

A user may input the cosmetic information using the input unit 13, and the control unit 15 may receive the input of the cosmetic information through the input unit 13.

For example, the control unit 15 may receive an input of at least one piece of cosmetic raw material information included in the cosmetic. Alternatively, the control unit 15 may receive an input of at least one piece of cosmetic raw material information and at least one piece of sub-information included in the cosmetic.

Alternatively, the control unit 15 may sense a cosmetic having a predetermined mass through a sensing module (not shown), and may analyze the sensed cosmetic to receive cosmetic raw material information. Alternatively, the control unit 15 may receive a cosmetic information signal including raw material information or sub-information of a cosmetic through a communication module (not shown). However, this is only exemplary, and the control unit 15 may receive the input of the cosmetic information in various ways.

When receiving the input of the cosmetic information, the control unit 15 may output the ultraviolet protection factor of the cosmetic according to the decision tree (S17).

The ultraviolet protection factor calculation unit 17 may obtain an ultraviolet protection factor corresponding to the received cosmetic information based on the decision tree, and may output the obtained ultraviolet protection factor through the output unit 14.

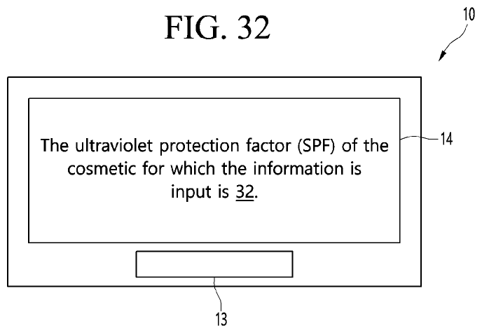

FIG. 32 is an exemplary view showing a method in which an ultraviolet protection factor calculating apparatus according to an embodiment of the present invention outputs an ultraviolet protection factor.

As shown in FIG. 32, the output unit 14 of the ultraviolet protection factor calculating apparatus 10 may display the ultraviolet protection factor of the cosmetic.

The control unit 15 may receive an input of the cosmetic information through the input unit 13, and may acquire the ultraviolet protection factor of the cosmetic for which the information is input to output the acquired ultraviolet protection factor to the output unit 14.

The control unit 15 may display the ultraviolet protection factor as at least one index such as SPF and PFA. For example, the output unit 14 may display a message such as “The sun protection factor (SPF) of the cosmetic for which the information is input is 32”. However, this is only an example, and the output unit 14 may display a message such as “The ultraviolet protection factor of the cosmetic for which the information is input is SPF 32, PA++”.

Again, FIG. 2 will be described.

After calculating the ultraviolet protection factor, the control unit 15 may determine whether or not a decision tree update command has been received (S19).

The control unit 15 may receive the decision tree update command through the input unit 13. When the decision tree update command is not received, the control unit 15 may calculate and output the ultraviolet protection factor of the cosmetic according to the already generated decision tree (S17) when receiving the input of the cosmetic information (S15) without generating a new decision tree.

Meanwhile, when the decision tree update command is received, the control unit 15 may accumulate and store additional cosmetic information and the ultraviolet protection factor in the database (S21).

That is, after calculating the ultraviolet protection factor, the control unit 15 may store the cosmetic information which is newly received when the ultraviolet protection factor is calculated and the ultraviolet protection factor calculated according thereto in the memory 11 to update the database, and may regenerate the decision tree based on the updated database, that is, may update the decision tree.

When receiving the input of the cosmetic information after updating the decision tree (S15), the control unit 15 may calculate and output the ultraviolet protection factor based on the updated decision tree (S17).

As shown in the flowchart shown in FIG. 2, the control unit 15 may deep-learn the criterion setting method of each node by calculating an ultraviolet protection factor when inputting new cosmetic information and updating the decision tree by merging a calculation result into the database, and accordingly, the prediction accuracy of the decision tree may be improved.

According to an embodiment of the present invention, the above-described method can be implemented as a processor code readable on a medium on which a program is recorded. Examples of the processor readable medium include those implemented in the form of ROM, RAM, CD-ROM, a magnetic tape, a floppy disk, optical data storage devices, and the like.

According to an embodiment of the present invention, the ultraviolet protection factor calculating apparatus can also be provided in the form of a terminal including a control unit having an ultraviolet protection factor calculation unit that calculates an ultraviolet protection factor through a stored decision tree, and an output unit, excluding except for a memory and a decision tree generation unit. It can also be provided in the form of a terminal. In this case, it can also be used as a method of updating the already stored decision tree by receiving a separate input.

The ultraviolet protection factor calculating apparatus described above cannot be applied so as to limit the configuration and method of the above-described embodiments, and the embodiments may also be configured by selectively combining all or a part of each of the embodiments so that various modifications can be made.

That is, the above-described descriptions are merely illustrative of the technological spirit of the present invention, and various changes and modifications may be made by those having ordinary skill in the art to which the present invention pertains without departing from the essential characteristics of the present invention.

Therefore, the embodiments disclosed in the present invention are not intended to limit the technological spirit of the present invention, but the embodiments are intended to describe, and the spirit and scope of the present invention is not limited by such embodiments.

The protection scope of the present invention should be construed by the following claims, and all technological spirits within the equivalent scope thereof should be construed as being included in the scope of right of the present invention.

1. A method for controlling an ultraviolet protection factor calculating apparatus, the method comprising:
storing, in a memory of the ultraviolet protection factor calculating apparatus, a database including data mapping a plurality of cosmetic information items with a plurality of ultraviolet protection factors, respectively;
generating, via a controller in the ultraviolet protection factor calculating apparatus, a decision tree having at least one of the plurality of cosmetic information items set as an explanatory variable and at least one of the plurality of ultraviolet protection factors set as a dependent variable based on the database;
receiving cosmetic input information;
determining, via the controller, an ultraviolet protection factor corresponding to the cosmetic input information based on an output of the decision tree; and outputting the ultraviolet protection factor corresponding to the cosmetic input information.

2. The method of claim 1, wherein the plurality of cosmetic information items include cosmetic identification information for one or more raw cosmetic material.

3. The method of claim 2, wherein the plurality of cosmetic information items further include at least one piece of sub-information.

4. The method of claim 3, wherein the sub-information includes at least one of a skin type, a minimum erythema dose (MED), a pigment presence, a pigment grade TiO2 content, a product formulation, and a product type.

5. The method of claim 1, wherein the outputting of the ultraviolet protection factor includes outputting a sun protection factor (SPF) or a protection factor (PFA) of Ultraviolet A light (UVA) calculated according to the decision tree.

6. The method of claim 1, further comprising:
receiving a decision tree update command;
in response to receiving the decision tree update command, updating the database by storing at least one additional cosmetic information item corresponding to the cosmetic input information and the ultraviolet protection factor corresponding to the cosmetic input information determined based on the output of the decision tree to generate an updated database; and
regenerating the decision tree based on the updated database to generate an updated decision tree.

7. A non-transitory computer-readable recording medium recording a program configured to perform the method of claim 1.

8. An ultraviolet protection factor calculating apparatus comprising:
an input interface configured to receive unit cosmetic input information;
a memory configured to store a database including data mapping a plurality of cosmetic information items with a plurality of ultraviolet protection factors, respectively; and
a controller configured to:
generate a decision tree having at least one of the plurality of cosmetic information items set as an explanatory variable and at least one of the plurality of ultraviolet protection factors set as a dependent variable based on the database,
receive the cosmetic input information via the input interface,
determine an ultraviolet protection factor corresponding to the cosmetic input information based on an output of the decision tree, and
output the ultraviolet protection factor corresponding to the cosmetic input information.

9. The apparatus of claim 8, wherein the plurality of cosmetic information items include cosmetic identification information for one or more raw cosmetic material.

10. The apparatus of claim 9, wherein the plurality of cosmetic information items further include at least one piece of sub-information.

11. The apparatus of claim 10, wherein the sub-information includes at least one of a skin type, a minimum erythema amount (MED), a pigment presence, a pigment grade TiO2 content, a product formulation, and a product type.

12. The apparatus of claim 8, wherein the ultraviolet protection factor output by the controller includes a sun protection factor (SPF) or a protection factor (PFA) of Ultraviolet A light (UVA) calculated according to the decision tree.

13. The apparatus of claim 8, wherein the controller is further configured to:
receive a decision tree update command;
in response to receiving the decision tree update command, update the database by storing at least one additional cosmetic information item corresponding to the cosmetic input information and the ultraviolet protection factor corresponding to the cosmetic input information determined based on the output of the decision tree to generate an updated database, and
regenerate the decision tree based on the updated database to generate an updated decision tree.

14. The apparatus of claim 8, wherein the decision tree includes a root node, at least one intermediate node, and at least one terminal node, and
wherein the root node and the intermediate node include classification criteria for cosmetic information, and the terminal node includes the ultraviolet protection factor.

15. The apparatus of claim 14, wherein the controller is further configured to determine the root node, the intermediate node, and the terminal node based on calculating a difference between a Gini coefficient before branching and the Gini coefficient after branching after sorting the database in ascending order according to a content amount of at least one cosmetic raw material and assuming points between sorted data values to be a branch.

16. The method of claim 1, wherein the decision tree includes a root node, at least one intermediate node, and at least one terminal node, and
wherein the root node and the intermediate node include classification criteria for cosmetic information, and the terminal node includes the ultraviolet protection factor.

17. The method of claim 16, further comprising:
determining, via the root node, whether a content amount of a cosmetic raw material included in the cosmetic input information is less than or equal to a predetermined value to determine a branching path of the decision tree; and
selecting a first intermediate node or a second intermediate node based on the branching path determined via the root node.

18. The method of claim 1, further comprising:
determining the root node, the intermediate node, and the terminal node based on calculating a difference between a Gini coefficient before branching and the Gini coefficient after branching after sorting the database in ascending order according to a content amount of at least one cosmetic raw material and assuming points between sorted data values to be a branch.

19. The method of claim 1, wherein the explanatory variable is an independent predictor variable.

20. A method for controlling an ultraviolet protection factor calculating apparatus, the method comprising:
receiving, via one or more processors in the ultraviolet protection factor calculating apparatus, cosmetic input information;
inputting, via the one or more processors, the cosmetic input information into a decision tree having at least one of a plurality of cosmetic information items set as an explanatory variable and at least one of a plurality of ultraviolet protection factors set as a dependent variable based on data mapping one or more of the plurality of cosmetic information items with one or more of the plurality of ultraviolet protection factors;
determining, via the one or more processors, an ultraviolet protection factor corresponding to the cosmetic input information based on an output of the decision tree; and
outputting the ultraviolet protection factor corresponding to the cosmetic input information.
